(19) United States
(12) Patent Application Publication
(10) Pub. No.: US 2026/0150430 A1
(43) Pub. Date: May 28, 2026

(54) Ultra-Wide-Band-Gap Semiconductor Optical Switches and Photodetectors

(71) Applicant: Massachusetts Institute of Technology, Cambridge, MA (US)

(72) Inventors: Jiahao Dong, Cambridge, MA (US); Rafael Jaramillo, Cambridge, MA (US)

(21) Appl. No.: 19/397,075

(22) Filed: Nov. 21, 2025

Related U.S. Application Data
(60) Provisional application No. 63/723,856, filed on Nov. 22, 2024.

(51) Int. Cl. H10F 55/25; H03K 17/78; H03K 17/94; H10F 30/221; H10F 55/20; H10F 77/00; H10F 77/124; H10F 77/50

(52) U.S. Cl. CPC H10F 55/25; H03K 17/78; H03K 17/941; H10F 30/2215; H10F 55/26; H10F 77/1243; H10F 77/1246; H10F 77/50; H10F 77/933

(57) ABSTRACT

A doped (ultra-)wide bandgap ((U)WBG) semiconductor can demonstrate photoconductivity when illuminated with sub-bandgap light. Forming a rectifying semiconductor-metal junction on a suitably doped (U)WBG semiconductor enables a photoconductive semiconductor switch (PCSS) actuated by visible light with strong photoresponsivity and fast operation. A PCSS realized in Ge-doped AlN achieves an on/off ratio over one million, and a photoresponsivity of 2.8 A/W under sub-bandgap illumination at center wavelength 455 nm and power density as low as 1 mW/cm². The PCSS can be turned off in under a second with a bias pulse that accelerates electron-hole recombination in the rectifying junction, quenching persistent photoconductivity. It also enables a semiconductor photodetector can measure very bright light without saturation or damage, and at elevated temperature. Such a photodetector realized in Ge-doped AlN demonstrates linear, non-saturating photoresponse for visible illumination power density up to ≥10.8 W/cm² and operating temperature up to ≥200° C.

### CROSS-REFERENCE TO RELATED APPLICATION(S)

This application claims the priority benefit, under 35 U.S.C. 119(e), of U.S. Application No. 63/723,856, filed Nov. 22, 2024, which is incorporated herein by reference in its entirety for all purposes.

### BACKGROUND

Wide band gap (WBG) semiconductors are semiconductors with band gaps above 2 eV, such as GaN, which has a band gap of 3.4 eV, and SiC, which has a band gap of approximately 3 eV. Ultra-wide bandgap (UWBG) semiconductors are semiconductors with band gaps well above 3.4 eV, such as Ga₂O₃ (5 eV band gap), diamond (5.5 eV band gap), and AlN (6 eV band gap). Optically controlled semiconductor switches made from WBG and UWBG semiconductors—herein referred to collectively as (U)WBG semiconductors—are of interest because they can switch high-voltage electrical power while being less susceptible to electromagnetic interference (EMI) than all-electrical switches. However, (U)WBG optically controlled semiconductor switches - also referred to as photoconductive semiconductor switches (PCSS)-are traditionally limited by a speed-gain tradeoff. Switches that demonstrate high gain usually suffer from slow operating speed, and in particular long turn-off times, due to persistent photoconductivity (PPC). For instance, PCSSs made from GaN (a WBG semiconductor) have high gain and therefore can be switched using rather low optical power levels but are very slow to turn off (time constant >10 seconds) due to persistent photocurrents. On the other hand, switches that do not suffer from slow turn-off typically suffer from small gain and require high-power illumination to operate.

Another consideration for optically controlled devices is the wavelength of the light used for control. The bandgap of (U)WBG semiconductors is in the ultraviolet (UV) region of the electromagnetic spectrum, and (U)WBG PCSSs are typically actuated using UV illumination. This presents challenges because UV illumination sources are typically less bright, less reliable, and more expensive than visible illumination sources.

Semiconductor photodetectors are based on the photoconductive response of semiconductor materials that are integrated into various devices. Most photodetector technologies (including photodiodes and charge-coupled devices) are made from silicon and suffer from poor performance in conditions of very bright light and/or very high operating temperature. The reasons for these performance limitations originate in the bandgap of silicon, which is much smaller than the bandgap of (U)WBG semiconductors.

(U)WBG semiconductors are, in their idealized form, transparent and non-responsive to visible light, but visible light responsivity can be imparted to U(WBG) semiconductors through chemical doping to create deep defects. Unintentional chemical impurities and other defects impart visible sensitivity—for instance, nitrogen in diamond is responsible for the yellowish color that is assessed when grading diamond gemstones. However, sensitivity to visible light alone does not mean that a chemical dopant is advantageous for making optoelectronic devices. Advantageous choices of chemical doping of (U)WBG semiconductors should enhance visible light photoconductivity and may be the basis for multiple technologies. Chemical doping of (U)WBG semiconductors is in general not well understood or controlled.

Studies of chemical doping of (U)WBG semiconductors have been largely focused on two goals: (1) achieving high concentrations of electrons or holes through shallow dopants, and (2) achieving good performance for photon-based quantum information processing and sensing using deep defects. By comparison, very little research attention has focused on the optoelectronic functionality of deep defects.

### SUMMARY

Aluminum nitride (AlN) is a UWBG semiconductor. Chemically doping AlN with certain elements can impart visible light sensitivity and photoconductivity. Ge-doping imparts visible light response and sizable photoconductivity to AlN when the Ge-doped AlN (herein, AlN:Ge) material is integrated into a semiconductor-metal (S-M) junction.

A PCSS based on AlN:Ge, suitably integrated into a S-M junction and with suitable control circuitry, combines strong visible light response and fast switching. An AlN:Ge PCSS circumvents the gain-frequency trade-off that limits other (U)WBG PCSS technologies: on one hand, its responsivity to visible light is higher than existing (U)WBG PCSSs; on the other hand, its turn-off response time can be reduced by orders-of-magnitude using short bias and illumination pulse sequences to suppress PPC.

An inventive PCSS can include a (U)WBG semiconductor suitably doped and integrated into a rectifying S-M junction. The dopant elements that may be used include but are not limited to Germanium. The resulting device may be a symmetrical M-S-M device featuring back-to-back rectifying S-M junctions. It may also be an asymmetrical M₁-S-M₂ device, wherein the S-M₁ junction is rectifying, and the S-M₂ junction is non-rectifying; here, M₁ and M₂ refer to different metallic elements, alloys, or stacks thereof. A voltage bias is applied across the metal electrodes. In the dark, the PCSS has a large electrical resistance, and little current flows between the electrodes. When the semiconductor is illuminated with light of a photon energy large enough to excite the deep defects, then defect ionization changes the size and shape of the depletion region of the rectifying S-M junction, making it narrower, thereby increasing the electrical conductivity of the device, and causing a large current to flow between the electrodes (S-M junctions). To switch the device off quickly, the illumination is turned off in sequence with a transient voltage pulse whose polarity is opposite to the originally applied bias voltage. This transient voltage pulse accelerates the recapture of majority charge carriers (e.g., electrons) by deep defects in the rectifying S-M junction, annihilating trapped minority charge carriers (e.g., holes). This restores the conductivity of the rectifying S-M junction to its starting value without illumination—i.e., the off state, at rest and at equilibrium—much more quickly than simply switching off the illumination and waiting.

An inventive photodetector can include a (U)WBG semiconductor suitably doped and integrated into a rectifying S-M junction. The dopant elements that may be used include but are not limited to Germanium. As above, the resulting device may be a symmetrical M-S-M device featuring back-to-back rectifying S-M junctions. It may also be an asymmetrical M₁-S-M₂ device, wherein the S-M₁ junction is rectifying, and the S-M₂ junction is non-rectifying. A voltage bias is applied across the metal electrodes, and the current that flows varies in proportion to the power density (measured in W/cm²) of illumination incident on the semiconductor. The photocurrent that flows across the metal electrodes varies linearly with illumination power density. This linear response can be achieved through suitable choices of chemical dopants and chemical dopant concentration in the (U)WBG semiconductor, a suitable design of the S-M junction, and a suitable choice of voltage bias during operation.

An inventive PCSS may include a layer of semiconductor (e.g., an ultra-wide bandgap III-nitride compound, such as AlN) that has a bandgap of at least 2 eV (e.g., >3.4 eV) and is chemically doped with chemical dopants (e.g., Ge) that form deep defects. The deep defects impart visible responsivity to the semiconductor. The PCSS can be operated by applying a voltage bias between a pair of metal electrodes on the semiconductor in such a way that at least one of the pair of metal electrodes forms a rectifying junction. Illuminating the layer of semiconductor with light having a photon energy less than the bandgap of the semiconductor causes the semiconductor to conduct current between the metal electrodes under the voltage bias. If desired, the light can be from a light source (e.g., a blue LED) that is formed directly on the semiconductor. Applying a transient voltage pulse (e.g., with a duration of 0.1-0.5 seconds) from a bias pulse generator with a polarity opposite to the voltage bias between the pair of metal electrodes suppresses persistent photocurrent in the layer of semiconductor and accelerates turn-off of the PCSS. Applying the transient voltage pulse suppresses the persistent photocurrent by annihilating minority charge carriers trapped at the rectifying junction.

An inventive photoconductor made of metal electrodes on an AlN layer doped with chemical dopants (e.g., Ge, Si, O, C, Fe, or Mn) forming deep defects can detect light having a photon energy as follows. While applying the bias voltage, light illuminates the AlN layer, and the deep defects at a rectifying junction formed by the AlN layer and one of the metal electrodes absorbs the light. This produces a measurable change in conductance of the rectifying junction. The light can be bright (e.g., it can be at a brightness of at least 1 W/cm²). Linearly increasing the brightness of the light produces a linear change in a current produced by the photodetector under a constant bias voltage. For example, the current can change linearly over a brightness range of about 1 mW/cm² to about 40 W/cm².

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally and/or structurally similar elements).

FIG. 1A shows a schematic cross-section of a lateral device using AlN:Ge as the photoconductive (U)WBG semiconductor and metallic elements, alloys, or stacks thereof used as the metal electrodes. This device is suitable for use as a PCSS or a photodetector.

FIG. 1B is a plot of dark current and photocurrent for an AlN:Ge PCSS as illustrated in FIG. 1A, measured under a DC bias sweep from −40 V to +40 V. The photocurrent measurement is made using illumination with wavelength 455 nm (approximately royal blue) and power density 1 mW/cm².

FIG. 1C is a plot of the transient photo response of an AlN:Ge PCSS as illustrated in FIG. 1A at a bias voltage of V_{DC}=+40 V under illumination power density of 1 mW/cm² (lower trace) and 10 mW/cm² (upper trace). The arrow indicates that the DC bias was switched from +40 V to −40 V at t=300 seconds. This suppresses PPC and turns off the PCSS.

FIG. 1D shows the semiconductor band diagram of the device illustrated in FIG. 1A for an applied bias of +40 V (top) and an applied bias of −40 V (bottom). The upper and lower solid lines represent the conduction and valence band levels, respectively, and the dashed lines denote the Fermi levels. Circles indicate trapped holes at the S-M rectifying junction (left). Shading illustrates how the transient voltage pulse changes the depletion width of the rectifying junction.

FIG. 1E shows an AlN-based PCSS device featuring vertical geometry.

FIG. 2A is a plot of the transient photo response of an AlN:Ge PCSS with a bias voltage of V_{DC}=40 V and an illumination power density of 48 mW/cm² for different choices for the turn-off bias pulse: 0.2 s pulse, 0.1 s pulse, and no pulse.

FIG. 2B shows a time series of applied bias voltage for the test results shown in FIG. 2A. The traces are offset vertically for clarity.

FIG. 2C is a plot illustrating the turn-off bias voltage pulse width used to suppress PPC to below 5%, for varying illumination power density. This plot shows that the pulse width to turn off the PCSS can be lowered by orders of magnitude, making the switch faster to operate. The dashed line is a power-law fit with an exponent 0.73.

FIG. 2D is a plot of PPC following turn-off pulses of varying width (pulse duration Δt from 0 to 0.5 seconds) for the AlN:Ge PCSS. The turn-off pulse ΔV_{DC}=−80 V was applied at t=40 s after the start of illumination with irradiance 10 mW/cm². The illumination stopped at the end of the turn-off pulse as in FIG. 2B.

FIG. 3A is a cross-sectional view of an example packaged device based on the AlN-based PCSS described herein.

FIG. 3B shows an AlN-based PCSS that is fully integrated with the illumination source by fabricating a light-emitting diode (LED) on top of the PCSS device layer, using a suitable fabrication method such as metal-organic chemical vapor deposition.

FIG. 4 shows a circuit with an AlN-based PCSS connected between a high-voltage DC supply and load with a bias pulse generator that applies bias pulses to the switch to facilitate turn-off of the switch.

FIG. 5A is a time series of the photoresponse for an AlN:Ge photodetector as illustrated in FIG. 1A, for an on-off illumination sequence with illumination power density varying from 10.8 W/cm² to 4.37 mW/cm². In each cycle, illumination was turned on for 10 s and then turned off for 20 s.

FIG. 5B illustrates that the AlN:Ge photodetector illustrated in FIG. 1A responds linearly to illumination power density. The points are experimental measurements. The line is a power-law fit with exponent demonstrating linear response.

FIG. 5C is a plot of the rise and fall time of the photoresponse of the AlN:Ge photodetector illustrated in FIG. 1A. Illumination is switched on at 20 ms, and off at 80 ms. The typical rise and fall times are 8.5 ms and 7.9 ms, respectively. The voltage bias used in this instance is 5 V. Other voltage biases may be used without compromising functionality.

FIG. 6A shows a time series of the photoresponse for an AlN:Ge photodetector as illustrated in FIG. 1A, at elevated temperatures (25, 100, and 200° C.) and for an on-off illumination sequence with illumination power density varying from 10.8 W/cm² to 4.37 mW/cm². In each cycle, illumination was turned on for 10 s and then turned off for 20 s.

FIG. 6B illustrates that the AlN:Ge photodetector response remains linear and unaltered up to at least 200 C. The data points and power-law fit lines are as in FIG. 5B.

FIG. 6C is a plot of the rise and fall time of the photoresponse of the AlN:Ge photodetector at 25, 100, and 200° C. The device response becomes faster at elevated temperature.

FIG. 7A is a cross-sectional view of an example photodetector package based on the device illustrated in FIG. 1A.

FIG. 7B shows an example measurement circuit including the packaged AlN-based photodetector of FIG. 7A connected between a DC voltage source and a load resistor.

FIG. 8 is a schematic of a two-dimensional array of AlN-based photodetectors suitable for use in an imaging system.

### DETAILED DESCRIPTION

To exploit photoconductivity due to chemical dopants that form deep defects (known as extrinsic photoconductivity) for optically switching a practical (U)WBG semiconductor device using sub-bandgap illumination, the chemical dopants should be carefully selected, and the synthesis should be suitably optimized. Dopants Si and Ge form deep defects instead of shallow donor states in UWBG AlN—and, more generally, in Ga₁₋ₓAlₓN with high Al content. As understood by those of skill in art of semiconductors, a deep defect is an impurity introduced into a semiconductor that creates an energy level within the bandgap and far from the conduction or valence band edge. This is distinct from a shallow defect, which is an impurity in a semiconductor that creates an energy level close to the conduction or valence band edge. Theoretical predictions show that chemical doping of AlN with Ge results in deeper defects than doping with Si. This makes AlN:Ge suitable for devices responsive to visible light, and AlN: Si suitable for devices responsive to infrared light. Other chemical dopants including but not limited to Ge, Si, C, O, Fe, and Mn may also be used to optimize sensitivity to different wavelengths of illumination.

Here, we disclose PCSSs and photodetectors based on epitaxial AlN films with high concentrations of Ge defects. The PCSS is excited using a light-emitting diode (LED) that emits light with a wavelength of 455 nm. Under irradiance as low as 1 mW/cm², the AlN switch achieves a photocurrent of 1.1 μA, an on/off current ratio equal to or greater than 10⁶, and an optical responsivity of 2.8 A/W. However, without further innovation, this photocurrent persists for several hours after the illumination is turned off. Understanding and eliminating this persistent photocurrent enables fast switching. Without being bound by any particular theory, this persistent photocurrent appears to be caused by charge trapping at the rectifying S-M junction. Applying a short voltage bias pulse to this S-M junction accelerates charge de-trapping, suppresses the persistent photocurrent, and turns off the device (opens the switch).

The PCSS and the photodetector disclosed here rely on careful selection of chemical dopants to form deep defects in an (U)WBG semiconductor and on the use of a rectifying S-M junction. As understood by those of skill in the art, a rectifying junction is a junction that has asymmetrical electrical conductivity with respect to the sign of applied voltage, so that it conducts far more current in one direction than in the other direction, for a fixed amplitude of applied voltage. Equivalently, a rectifying junction is a junction in which there is a net transfer of majority charge carriers from the semiconductor to the metal at equilibrium, resulting in a fixed internal electric field. A rectifying junction is marked by a depletion region in the semiconductor adjacent to the metal.

The rectifying S-M junction in an inventive PCSS controls the electrical conductivity of the device, such that when put under reverse bias, the junction resistance of the rectifying S-M junction is much larger than total series resistance from other sources. When this applies, then the state and operation of the device depends primarily on the width of the depletion region of the reverse-biased S-M junction, without being bound by any particular theory describing the electrical conductivity of the junction or of the other sources of series resistance.

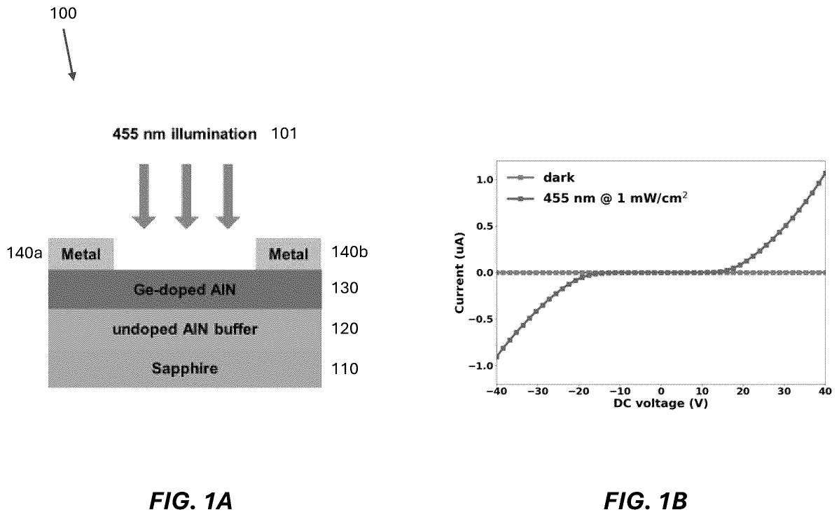

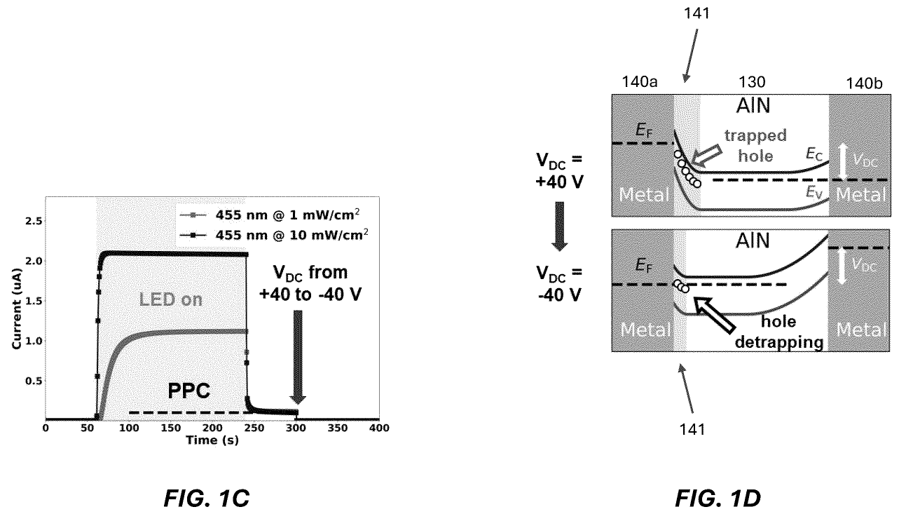

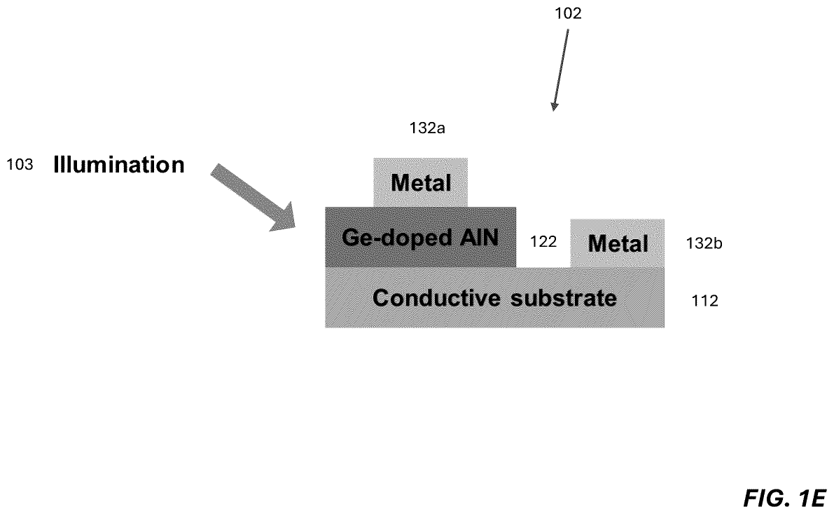

FIG. 1A shows a schematic cross section of a lateral semiconductor device 100, also called an AlN semiconductor stack or AlN die, based on AlN:Ge, used here as a PCSS or a photodetector. The device includes a layer 130 of heavily Ge-doped AlN with a Ge concentration of 2×10¹⁹ cm⁻³, on an undoped AlN layer 120, which is on a sapphire substrate 110. (These layers can be hundreds of nanometers to several microns thick, e.g., 100 nm to 2 μm thick, and the Ge concentration of the doped AlN layer 130 can be 1×10¹⁸ cm⁻³ or higher, e.g., 2, 3, 4, 5, 6, 7, 8, 9, 10, 15, or 20×10¹⁸ cm⁻³ or higher.) The Ge-doped AlN layer 130 and undoped AlN layer 120 can be deposited using metal-organic chemical vapor deposition or any other suitable technique. The undoped AlN layer 120 supports the growth of the Ge-doped AlN layer 130 on the substrate 110 and does not directly influence the device performance.

The device 100 also includes a pair of electrodes 140a, 140b (collectively, electrodes 140) on opposite edges of the exposed upper surface of the AlN:Ge layer 130. In the example shown in FIG. 1A, the electrodes 140 are rectangular metal contacts composed of Ti/Au (5/50 nm) deposited by electron-beam evaporation, followed by a standard liftoff process. At least one of the metal contacts should form a rectifying S-M junction on the AlN:Ge layer, depending on work function of the metal contacts and carrier concentration in the AlN:Ge layer. If the metal electrodes 140a and 140b are identical, both could form rectifying S-M junctions on the AlN:Ge layer. In this example, the electrodes 140 have the same widths (300 μm) and contact areas (2.7 mm²), but the electrodes in other examples may have different sizes, shapes, and/or compositions. The semiconductor-metal contacts are rectifying due to the low concentration of shallow defects in AlN. The electrodes 140 are spaced apart by about 5 μm, leaving a portion of the upper surface of the Ge-doped AlN layer 130 exposed to incident light, which in the case of the following experiments was 455 nm illumination 101 from an LED (not shown). When the device 100 is used as a PCSS, it can be actuated with an irradiance of 1 mW/cm² or more. The separation between the electrodes should be at least as wide as the depletion width of the rectifying S-M junction, which varies with the semiconductor, the chemical dopant(s), and the dopant concentration(s). The electrical measurements detailed below were performed in a two-probe configuration using an electrometer in a probe station surrounded by a dark enclosure.

FIG. 1B shows both the dark current and photocurrent of the device 100 measured under a bias voltage sweep from −40 V to +40 V. In practice, the bias voltage may range from a few volts or tens of volts (e.g., 2-20 V) to up to hundreds of volts or kilovolts (e.g., 100 V to 5 kV and above) for power and MVAC applications (e.g., electrical grids or transformers). At a DC bias voltage of +40 V, the dark current was about 3 pA while the photocurrent was 1.1 μA, yielding an on-off current ratio of six orders of magnitude with an irradiance of just 1 mW/cm². This corresponds to an optical responsivity of 2.8 A/W. The photon energy used for illumination is 2.7 eV (455 nm), which is far below the AlN bandgap of 6.1 eV. This suggests that the observed photocurrent is due to photoionization of deep defect states, known as extrinsic photoconductivity. The nonlinear relationship between photocurrent density and DC voltage shown in FIG. 1B implies that higher responsivity and current could be achieved by operating at higher voltage, surpassing previously-reported PCSSs made using (U)WBG semiconductors and triggered by sub-bandgap illumination, whose responsivity is typically on the order of 10⁻⁵ A/W.

An Ultra-Wide-Bandgap (UWBG) Photoconductive Semiconductor Switch (PCSS) that Operates with Visible Light and Features Fast Operation

FIG. 1C shows transient photoresponse of an AlN-based PCSS under 1 mW/cm² irradiance (lower trace) and 10 mW/cm² irradiance (upper trace) from an LED emitting light at a wavelength of 455 nm. The transient photoresponse depends on optical power; turn-on was accelerated by ten times with an optical fluence increase from 1 mW/cm² to 10 mW/cm². However, FIG. 1C shows a persistent photocurrent (PPC) of 0.1 μA after the LED was turned off, regardless of the irradiance. PPC is asymmetric in the AlN photo-switch: changing DC bias voltage V_{DC} from +40 V to −40 V at t =300 s caused the PCC to drop instantaneously to 0 as indicated by the arrow in FIG. 1C.

Without being bound by any particular theory, the asymmetric PPC observed in the AlN-based PCSS may be caused by minority charge trapping at the rectifying S-M junction formed by electrode 140a and the Ge-doped AlN layer 130. Upon sub-bandgap excitation, deep defects can release electrons to the conduction band and become positively charged. The distribution of photogenerated carriers is not uniform but skewed by the electric field at the rectifying S-M junction. Under a bias voltage V_{DC}=+40 V, the rectifying S-M junction formed by electrode 140a and the Ge-doped AlN layer 130 is subject to reverse bias; here, photogenerated electrons are much more depleted than at the other S-M junction. Therefore, after the light is turned off, deep defects at the reverse-biased, rectifying S-M junction remain positively charged because there are few electrons available for recombination. In other words, minority charge carriers (holes) are trapped at the reverse-biased, rectifying S-M junction when the light is turned off, leading to PPC.

FIG. 1D shows band diagrams for the device 100 under DC bias voltages of +40 V (top) and −40 V (bottom), with circles representing holes trapped by positively charged deep defects. The hole trapping is asymmetrical, with more holes trapped at the reverse-biased, S-M rectifying junction 141 (left). The trapped positive charge causes the rectifying S-M junction 141 to become thinner (indicated the change in width of the grey shading from top to bottom in FIG. 1D), which makes the device more electrically conductive, leading to PPC. When V_{DC} changes from +40 V to −40 V, the PPC disappears because there are few if any holes trapped at the other S-M junction (right).

According to the Shockley-Read-Hall (SRH) mechanism, the rate of hole detrapping by electron recapture is proportional to exp[−(E_{C}−E_{F})/k_{B}T], where E_{C}−E_{F} is the distance between the conduction band and the Fermi level. FIG. 1D suggests that the number of trapped holes should decrease when V_{DC} changes from +40 V to −40 V because the Fermi level shifts closer to the conduction band. When the Fermi level shifts closer to the conduction band, there are more electrons available to recombine with trapped holes, returning the deep defects to their charge-neutral state. This makes the depletion region of the junction wider, and makes the device less electrically conductive, turning off the switch. Using a bias pulse with an amplitude ΔV_{DC}=−80 V should reduce or annihilate trapped charge and facilitate device turn-off. The bias pulse should accelerate device turn-off as long as it has an opposite sign to V_{DC}, i.e., a transient bias pulse with an amplitude ΔV_{DC}=−10 V, ΔV_{DC}=−20 V or ΔV_{DC}=−40 V should also work if V_{DC}=+40 V. The duration of the bias pulse may vary depending on the amplitude of the bias pulse.

FIG. 1E shows a vertical PCSS 102. The device 100 illustrated in FIG. 1 features lateral geometry and is fabricated on an electrically insulating layer. The PCSS 102 illustrated in FIG. 1E features vertical geometry and is fabricated on an electrically conducting layer (conductive substrate 112). It includes a Ge-doped AlN layer 122 sandwiched between the conductive substrate 112 and a metal electrode 132a on the heavily Ge-doped AlN layer 132. Another metal electrode 132b sits on the conductive substrate 112. Together, the two metal electrodes 132a, 132b can be used to apply a bias voltage to the Ge-doped AlN layer 122, with the metal electrode 132a and the Ge-doped AlN layer 122 forming a rectifying S-M junction. A device with vertical geometry, such as the fin-or ridge-like profile illustrated in FIG. 1E, may offer engineering advantages over a device with lateral geometry because the chemical doping of the AlN layer 122 can be spatially modulated in the range from 1×10¹⁶ cm⁻³ to 2×10²⁰ cm⁻³ to optimize device performance.

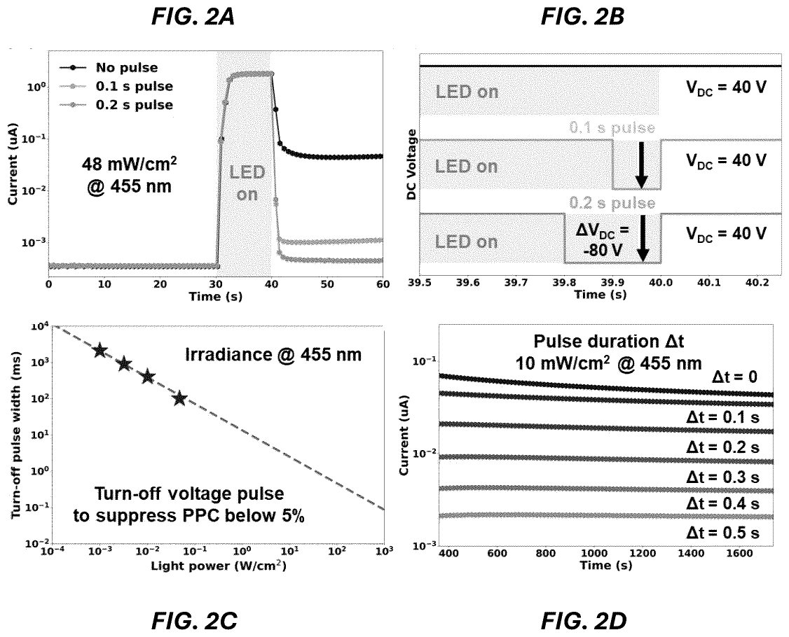

FIG. 2A shows the AlN-based PCSS transient photoresponse without a bias pulse (upper trace), with a 0.1 s bias pulse (middle trace), and with a 0.2 s bias pulse (lower trace); the bias pulse amplitude was set to ΔV_{DC}=−80 V in both cases with bias pulses. The dark current before the light is turned on is about 3 pA, not 0.3 nA as in FIG. 2A. (The electrometer used to measure the transient photo-response has a lowest measurable current of 0.3 nA with a 2 μA current range; the dark current before the light was turned on was measured to be 3 pA with a 20 pA current range.)

FIG. 2B shows the DC voltage and illumination as a function of time for the three transient measurements in FIG. 2A. As shown in FIG. 2A, without a bias pulse, PPC occurred with a time constant of 3.5 hours; with a 0.1 s bias pulse, the magnitude of PPC was reduced to 2%, while with a 0.2 s bias pulse, PPC was almost completely suppressed. These results indicate that a short bias pulse can effectively suppress PPC and turn off the PCSS, which significantly improves device operating speed. The turn-off time also depends on the power level of the light used to actuate the switch. As shown in FIG. 2B, the ΔV_{DC}=−80 V bias pulse was applied before the LED was turned off.

FIG. 2C shows the measured turn-off pulse width as a function of the optical power used to actuate the switch. Here, the turn-off time is defined as the pulse duration that suppresses the PPC by 95%. The pulse amplitude was set to ΔV_{DC}=—80 V in the experiments illustrated in FIG. 2C. The dashed line in FIG. 2C is a power law fit to the measurements with an exponent of 0.73. Without being bound by any particular theory, the dependence of turn-off time on optical power can be explained as light-assisted hole detrapping, i.e., the hole detrapping rate increases with optical power because of increased accessibility of electrons for recombination. Due to the limitations of the experimental set-up, the maximum light power used here was 48 mW/cm², and the minimum turn-off time was 100 ms. According to FIG. 2C, when scaled to higher light power density, the AlN photo-switch's turn-off time should be shorter, which enables higher switching frequencies (e.g., kHz switching frequencies). For instance, the turn-off time is 125 ms at 50 mW/cm² and 2.4 ms at 10 W/cm² according to the power law fit in FIG. 2D. A turn-off time of 125 ms enables a maximum switching frequency of 8 Hz while a turn-off time of 2.4 ms enables a maximum switching frequency of 417 Hz.

In addition to turning off the PCSS, the bias pulse can also be used to program device conductivity, e.g., for non-volatile memory applications. FIG. 2D shows the PPC of an AlN photo-switch after a bias pulse under an optical power of 10 mW/cm². The bias pulse was applied at t=40 s; the amplitude was set to ΔV_{DC}=—80 V, and the bias pulse width Δt was varied from 0 to 0.5 s. Instead of being suppressed, the PPC was programmed to a series of distinct levels. Possibly because of the long time constants (e.g., 3.5 hours), the PPC decayed only slightly after 20 minutes. The pulse-programmable PPC makes an AlN photo-switch suitable for non-volatile switching.

### Example Device, Package and Circuit Configurations of an Ultra-Wide-Bandgap (UWBG) Photoconductive Semiconductor Switch (PCSS) that Operates with Visible Light and Features Fast Operation

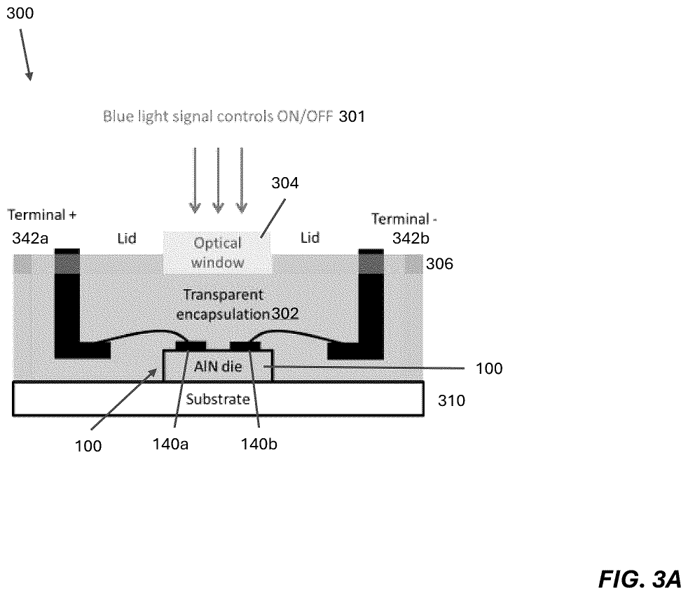

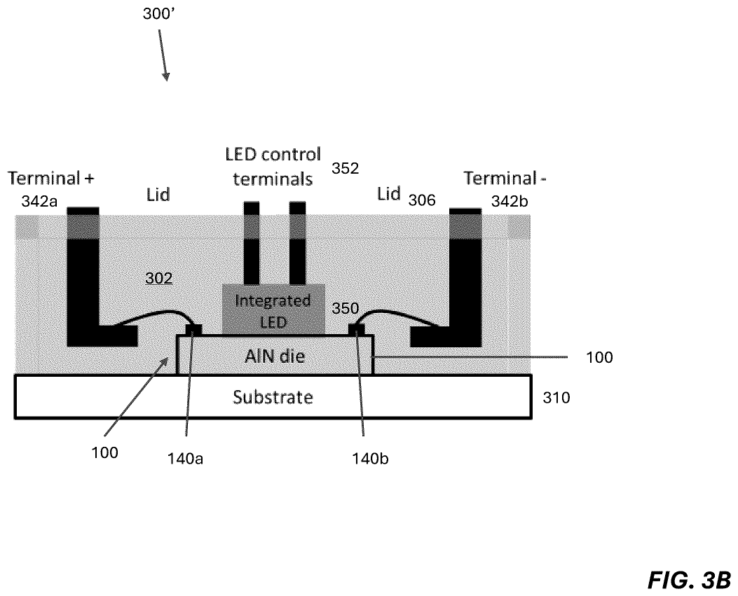

FIGS. 3A and 3B show different AlN-based PCSS packages 300 and 300', respectively. The PCSS package 300 in FIG. 3A includes the AlN-semiconductor stack 100 shown in FIG. 1A, with the Ge-doped AlN layer 130, undoped AlN layer 120, and sapphire substrate 110 forming an AlN optical switch die that is bonded onto the thermally conductive but electrically insulating substrate 310. The electrodes 140a and 140b on the AlN optical switch die are wire-bonded to electrical terminals 342a and 342b, respectively, which provide external connection points for a load circuit. The assembly is enclosed with a lid 306 and filled with a transparent encapsulant 302. The lid 306 includes an optical window 304 configured to transmit blue light 301 to the AlN optical switch die (and in particular the Ge-doped AlN layer 130) for optical control of the PCSS.

The AlN-based PCSS package 300′ in FIG. 3B features an AlN optical switch die (Ge-doped AlN layer 130, undoped AlN layer 120 and sapphire substrate 110) that is fully integrated with an LED 350. This LED 350 can be fabricated directly on top of the PCSS device layer (Ge-doped AlN layer 130) using a suitable fabrication method such as metal-organic chemical vapor deposition. The LED 350 is contained within the lid 306, which can be opaque (no window), albeit with electrical control terminals 352 accessible from outside the package for turning on and off the LED 350 and actuating the PCSS.

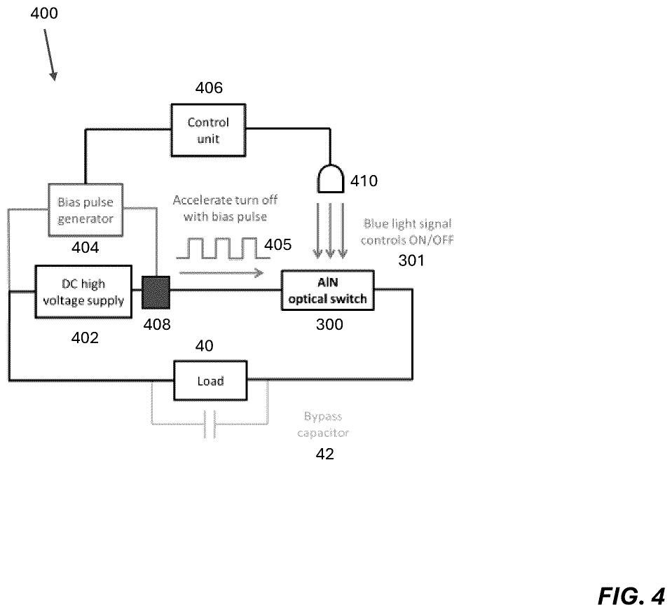

FIG. 4 shows the PCSS optical switch package 300 coupled in series with a load 40 and a high-voltage DC supply 402 for biasing the PCSS. The load 40 is in parallel with a bias capacitor 42, and the high-voltage DC supply 402 is in parallel with a bias pulse generator 404. The output of the bias pulse generator is coupled capacitively to the high voltage supply line with a bias tee 408. A control unit 406 connected to the bias pulse generator 404 and to a blue light LED 410 controls the operation of the PCSS by turning on and off both the blue light LED 410 and the bias pulse generator 404. Blue light 301 from the blue light LED 410 shines on the PCSS package 300. When illuminated by the blue-light control signal 301, the PCSS 300 turns ON, allowing current to flow through the load 40. In the absence of illumination, the PCSS 300 remains OFF, blocking current flow. The bias pulse generator 404 applies bias pulses 405 to facilitate turn-off of the switch, while the bypass capacitor (filter) 42 connected in parallel with the load 40 prevents the bias pulses from affecting the load 40. Both the blue-light control signal 301 and the bias pulses from the bias pulse generator 404 are coordinated by the control unit 406. The exact sequencing of illumination and the bias pulse used to turn the PCSS device off depend on the desired operating speed and the acceptable leakage current in the OFF state, and can be determined on an application-specific basis. The experimental data and best-fit line presented in FIG. 2C are suggestive of how these details might be chosen.

Operational Advantages and Example Use Cases of a UWBG PCSS that Operates with Visible Light and Features Fast Operation

The PCSS described herein affords an operational advantage over electrically controlled high voltage switches (e.g., field effect transistors) for fast and reliable switching of high voltage circuitry in environments with a high degree of electromagnetic interference (EMI). This advantage follows from the physical separation of the control circuitry (e.g., control unit 406 in FIG. 4) from the high-voltage-carrying conductors. This physical separation reduces the likelihood of electromagnetic interference affecting the control circuitry, which could lead to unintentional switching events.

Advantages for fast and reliable switching also follow from the higher-speed operation made possible by control of trapped charge at a rectifying S-M junction, as described above and illustrated in FIG. 1D. Faster operating speed makes the inventive PCSS technology viable for switching on a sub-second timescale.

Advantages for fast and reliable switching also follow from the use of visible illumination as opposed to UV illumination to actuate the PCSS. Sources of visible illumination are far easier to integrate into device technology, less expensive, more powerful, and more reliable than sources of UV illumination.

Examples of fast and reliable switching of high voltage circuitry in environments with a high degree of EMI include electrical grid substations, power supplies for data centers, power control circuits for electrified transportation, and power control circuits for defense applications.

A PCSS comprised of a UWBG semiconductor also provides an advantage of being able to switch higher voltages than switches comprised of semiconductors with lower bandgaps. This advantage follows from the breakdown electric field strength of UWBG AlN, which is higher than most other semiconductors (e.g., Si, GaN, SiC, Ga₂O₃, diamond).

As a result of being able to switch higher voltage, a power supply based on UWBG PCSS technology may use fewer switches to step down voltage (e.g., from high-voltage or medium-voltage transmission to voltage appropriate for street-level distribution or data center use), and therefore be more physically compact and easier to design and operate than a power supply based on switches comprised of lower-bandgap semiconductors.

An inventive PCSS also offers advantages for optical control of strong electric fields, which may be used for instance to control pattern formation during manufacturing. The conductivity of an (U)WBG semiconductor in a PCSS can be varied quickly between very high and very low values (e.g., as shown in FIG. 2A), using low-power visible illumination. This provides an advantage for controlling liquid-crystal based optical masks (e.g., patterned light valves) that may be used for instance to pattern high power laser beams for additive manufacturing.

### An Ultra-wide-bandgap Semiconductor Photodetector for Ultra-bright Light

The device 100 in FIG. 1A can also be used as a photodetector that measures the irradiance of incident light by converting incident light into electrical photocurrent. It is especially useful for measuring ultra-bright light without saturation. The mechanism that enables non-saturating response to ultra-bright light is related to optical control of the rectifying S-M junction in a suitably doped (U)WBG semiconductor. The photoresponse of the device depends on the chemical dopant and its concentration in the (U)WBG semiconductor—here, for example, Ge doped to a concentration of 2×10¹⁹ cm⁻³.

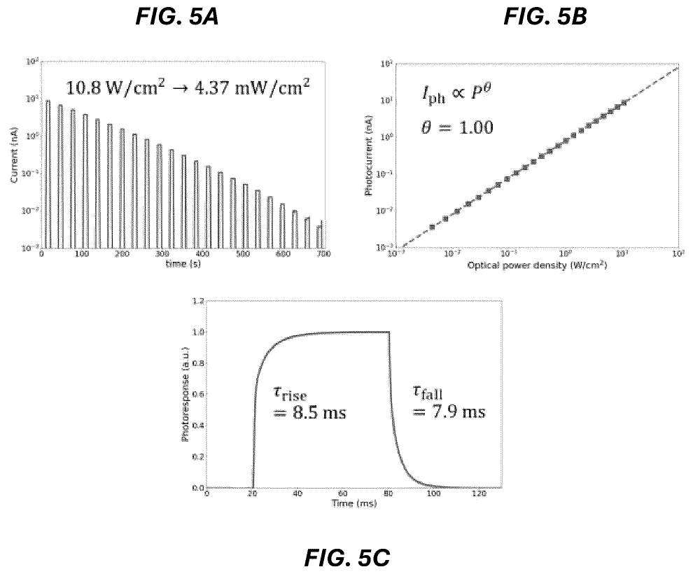

FIGS. 5A-5C show measurements of the current flowing through the device. The bias voltage used here is 5 V. Other bias voltages may be used without compromising functionality. The device is electrically insulating in the dark, exhibiting a dark current below 1 pA, whereas it conducts current when illuminated under blue or UV light, e.g., with light at a 455 nm center wavelength. FIG. 5A is a plot of the photoresponse vs. time under cyclic illumination with power density varying from 10.8 to 0.004 W/cm². FIG. 5B presents measurements of the photocurrent vs. illumination power density, and a best-fit of the experimental data to a power law I∝P^{θ}, where I is photocurrent, P the irradiance and θ the scaling exponent. A value of θ=1.00 confirms a linear dependence of photocurrent on optical power density, indicating that the photodetector remains unsaturated under very bright illumination. FIG. 5C shows the time-dependent response to turning light on and off at room temperature, with a 90% rise time of 8.5 ms and a 90% fall time of 7.9 ms.

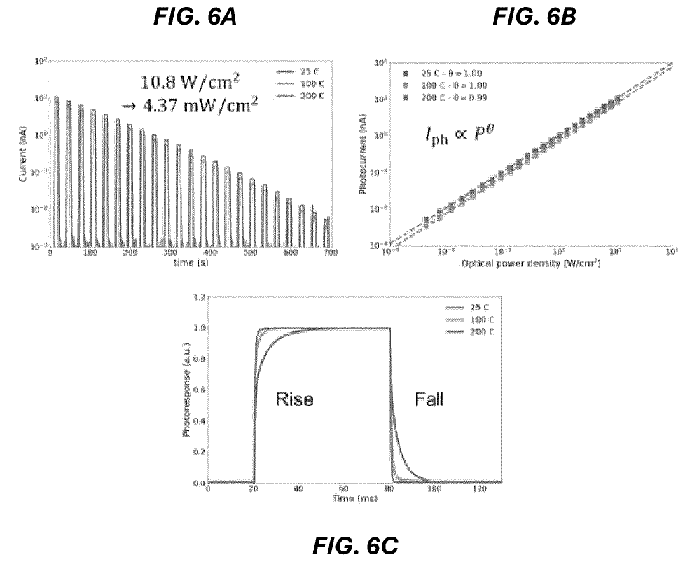

FIGS. 6A-6C show that the photodetector retains excellent function at elevated temperature. The voltage bias used here is 5 V. Other voltage biases may be used without compromising functionality. FIG. 6A shows the photoresponse versus time under cyclic illumination with power density varying from 10.8 to 0.004 W/cm² and at temperatures of 25° C., 100° C., and 200° C. The device has a dark current of approximately 1 pA at 200° C. FIG. 6B presents measurements of the photocurrent vs. illumination power density, and a best-fit of the experimental data at each temperature to a power law I∝P^{θ}. The device exhibits excellent linearity and non-saturated optical response at all temperatures: at 25° C., θ=1.00; at 100° C., θ=1.00; at 200° C., θ=0.99 (1% deviation from linearity). FIG. 6C shows the time-dependent response to turning light on and off at elevated temperature. The device operation becomes faster at elevated temperature. At 200° C., the photodetector has a 90% rise time of 0.9 ms and a 90% fall time of 0.8 ms.

A photodetector based on well-designed chemical doping and a rectifying M-S junction in an (U)WBG semiconductor can measure high optical power (e.g., up to at least 10.8 W/cm²) with linear response, without suffering damage, and at elevated operating temperature. In contrast, conventional semiconductor photodetectors—including photodiodes, charge-coupled device (CCD) and complementary metal-oxide-semiconductor (CMOS) sensors—suffer from saturation and damage at moderate-to-high optical power; upper limits of operation without attenuation are typically 0.01-0.1 W/cm². Detecting bright light with a semiconductor photodetector typically involves using optical attenuators or filters to reduce the intensity reaching the device, complicating system design and operation, and adding cost, weight, and size. Thermal photodetectors measure optical power as heat and typically do not suffer from saturation. However, thermal photodetectors are usually very slow, e.g., with response times >1 s. Thermal photodetectors also cannot be practically integrated into focal plane arrays for imaging systems.

### Example Package and Measurement Circuit for an UWBG Photodetector for Ultra-bright Light

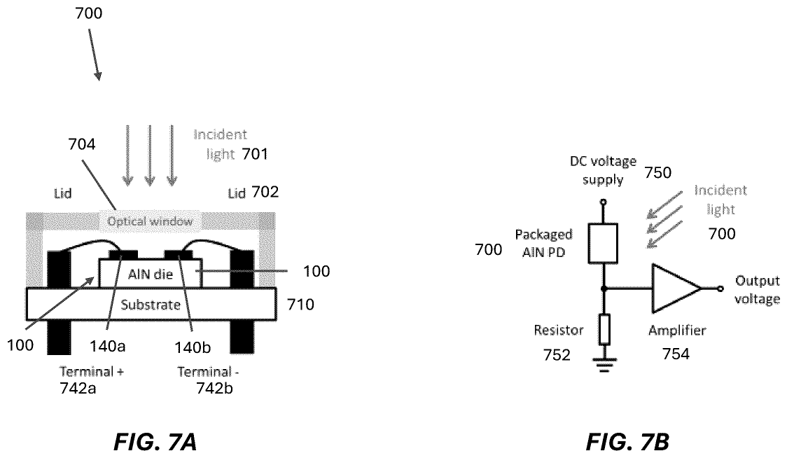

FIG. 7A shows an example AlN-based photodetector package 700 including the AlN semiconductor stack 100 shown in FIG. 1A, with the Ge-doped AlN layer 130, undoped AlN layer 120, and sapphire substrate 110 forming an AlN photodetector die, mounted on a thermally conductive and electrically insulating substrate 710. This AlN-based photodetector package 700 is similar to the PCSS switch package 300 in FIG. 3A, but without the transparent encapsulant 302. Device electrodes 140a, 140b on opposite edges of an exposed surface of the AlN photodetector die 100 are wire-bonded to respective electrical terminals 742a, 742b that serve as external connection points for measurement or circuit integration. In operation, the electrical terminals 742a, 742b apply a bias voltage (e.g., of less than 10 V) to the device electrodes 140 a, 140 b. This assembly is enclosed by a protective lid 702 incorporating an optical window 704 that permits incident light 701 to reach the AlN photodetector die 100 while shielding the AlN photodetector die 100 from the environment.

FIG. 7B shows an example measurement circuit with the packaged AlN photodetector (PD) 700 connected between a DC voltage source 750 and a load resistor 752. When illuminated, the packaged AlN photodetector 700 generates a photocurrent whose amplitude is proportional to the irradiance of the incident light. This photocurrent produces a photovoltage across the load resistor 752, which is then amplified with an amplifier 754 and read out by an external circuit (not shown). The irradiance of the incident light can be determined from the measured output voltage.

### An Imaging Array Using UWBG Semiconductor Photodetectors for Ultra-Bright Light

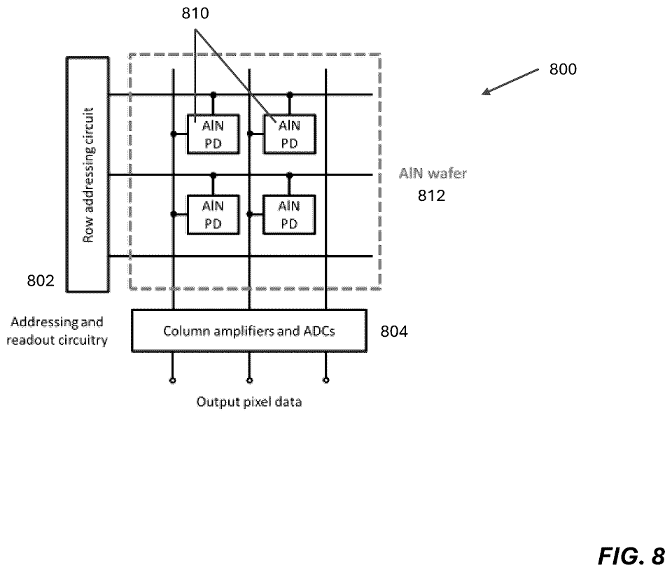

FIG. 8 shows AlN photodetector (PD) 810 integrated into a two-dimensional array 800 for imaging applications. Each AlN photodetector 810 includes device electrodes and a layer of Ge-doped AlN, possibly grown on a layer of undoped AlN that sits on a substrate. In this configuration, multiple AlN photodetectors 810 are fabricated on the same AlN wafer 812 (e.g., multiple AlN photodetectors are patterned in same Ge-doped AlN layer) and connected to external row addressing circuitry 802 and column readout circuitry 804. The row addressing circuitry 812 sequentially selects each row of AlN photodetectors 810, while the irradiance signals from the AlN photodetectors 810 in that row are read out through respective column amplifiers and analog-to-digital converters (ADCs) 804. By scanning all rows, irradiance signals from all pixels (all AlN photodetectors 810) are collected and combined to reconstruct an image.

### Operational Advantages and Example Use Cases of an UWBG Semiconductor Photodetector For Ultra-Bright Light

The photodetector described herein provides operational advantages over existing photodetector technologies in situations benefiting from accurate, reliable, and fast measurement and imaging of very bright emission sources. These advantages follow from the use of a rectifying S-M junction formed by a metal electrode and a (U)WBG semiconductor that is suitably chemically doped to impart visible light sensitivity. Due to this rectifying S-M junction, an inventive photodetector exhibits linear response without saturation or damage for much brighter illumination than other semiconductor photodetector technologies and much faster response than thermal sensors.

Unlike thermal sensors, the inventive photodetectors, being planar semiconductor devices, can be fabricated into focal plane arrays for imaging applications.

Compared to existing semiconductor photodetectors or thermal sensors, another advantage of the inventive photodetectors is that they can operate reliably at elevated temperature (FIG. 8) by virtue of being comprised of an (U)WBG semiconductor with outstanding thermal stability.

Example applications of inventive photodetectors include monitoring and controlling industrial processes that involve very bright light emission, including but not limited to laser welding, laser powder bed additive manufacturing, and combustion-based processes.

Further example applications include monitoring rocket engines and similar propulsion technologies, including but not limited to ballistic launch events.

Further example applications include designing light-based detectors and communications systems that are immune to adversarial attack by laser speckle.

### Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of actuating a photoconductive semiconductor switch (PCSS) comprising a layer of semiconductor having a bandgap of at least 2 eV and chemically doped with chemical dopants forming deep defects that impart visible responsivity to the semiconductor, the method comprising:
applying a voltage bias between a pair of metal electrodes on the semiconductor in such a way that at least one of the pair of metal electrodes forms a rectifying junction;
illuminating the layer of semiconductor with light having a photon energy less than the bandgap of the semiconductor, the light causing the semiconductor to conduct current between the metal electrodes under the voltage bias; and
applying, between the metal electrodes, a transient voltage pulse with a polarity opposite to the voltage bias, the transient voltage pulse suppressing persistent photocurrent in the layer of semiconductor and accelerating turn-off of the PCSS.

2. The method of claim 1, wherein the bandgap of the semiconductor is greater than 3.4 eV.

3. The method of claim 1, wherein the semiconductor comprises an ultra-wide bandgap III-nitride compound.

4. The method of claim 1, wherein the semiconductor comprises aluminum nitride and the chemical dopants comprise germanium.

5. The method of claim 1, wherein applying the transient voltage pulse suppresses the persistent photocurrent by annihilating minority charge carriers trapped at a rectifying junction between the semiconductor and one of the metal electrodes.

6. The method of claim 1, wherein applying the transient voltage pulse comprises applying the transient voltage pulse for a duration of about 0.1 seconds to about 0.5 seconds.

7. A photoconductive switching circuit comprising:
a semiconductor having a bandgap of at least 2 eV and doped with chemical dopants that impart visible responsivity to the semiconductor;
metal electrodes fabricated on the semiconductor in such a way that at least one of the metal electrodes is a rectifying junction;
a voltage source, electrically connected to the metal electrodes, to apply a bias voltage across the metal electrodes;
a light source, in optical communication with the semiconductor, to illuminate the semiconductor with light having a photon energy less than the bandgap of the semiconductor, the light causing the semiconductor to conduct current between the metal electrodes under the bias voltage; and
a bias pulse generator, electrically connected to the metal electrodes, to apply a transient voltage pulse with a polarity opposite the bias voltage to the metal electrodes, the transient voltage pulse suppressing persistent photocurrent in the semiconductor.

8. The photoconductive switching circuit of claim 7, wherein the semiconductor comprises a III-nitride semiconductor.

9. The photoconductive switching circuit of claim 7, wherein the semiconductor comprises aluminum nitride and the chemical dopants comprise germanium.

10. The photoconductive switching circuit of claim 7, wherein the light source is configured to illuminate the semiconductor with visible light.

11. The photoconductive switching circuit of claim 7, wherein the light source is formed directly on the semiconductor.

12. The photoconductive switching circuit of claim 7, wherein the transient voltage pulse annihilates minority charge carriers trapped at a rectifying junction between the semiconductor and one of the metal electrodes.

13. The photoconductive switching circuit of claim 7, wherein the transient voltage pulse has a duration of about 0.1 seconds to about 0.5 seconds.

14. A method of detecting light having a photon energy less than a bandgap of AlN with a photodetector comprising a pair of metal electrodes on an AlN layer doped with chemical dopants forming deep defects, at least one of the pair of metal electrodes forms a rectifying junction with the AlN layer, the method comprising:
applying a bias voltage across the pair of metal electrodes;
while applying the bias voltage, illuminating the AlN layer with the light, the deep defects at the rectifying junction absorbing the light; and
measuring a change in conductance of the rectifying junction caused by absorption of the light by the deep defects.

15. The method of claim 14, wherein the light has a brightness of at least 1 W/cm².

16. The method of claim 14, wherein the chemical dopants comprise at least one of Ge, Si, O, C, Fe, or Mn.

17. The method of claim 14, wherein linearly increasing a brightness of the light produces a linear change in a current produced by the photodetector under a constant bias voltage.

18. The method of claim 17, wherein the current changes linearly over a brightness range of about 1 mW/cm² to about 40 W/cm².
